(19) United States
(12) Patent Application Publication
(10) Pub. No.: US 2008/0229161 A1
(43) Pub. Date: Sep. 18, 2008

(54) MEMORY PRODUCTS AND MANUFACTURING METHODS THEREOF

(75) Inventors: Cheng-Hung Lee, Hsinchu County (TW); Ching-Wei Wu, Hsinchu City (TW); Chung-Cheng Chou, Hsinchu City (TW); Hung-Jen Liao, Hsinchu City (TW)

Correspondence Address: THOMAS, KAYDEN, HORSTEMEYER & RISLEY LLP, 600 GALLERIA PARKWAY, 15TH FLOOR, ATLANTA, GA, 30339, US

(73) Assignee: TAIWAN SEMICONDUCTOR MANUFACTURING CO., LTD., Hsin-Chu (TW)

(21) Appl. No.: 11/686,996

(22) Filed: Mar. 16, 2007

(51) Int. Cl. G11C 29/00

(52) U.S. Cl. 714/710

(57) ABSTRACT

Memory products and manufacturing methods thereof. A memory product comprises at least one memory cell and at least one redundancy memory cell. The memory cell and the redundancy memory cell have different physical or electronic properties. The redundancy memory cells are used as repair schemes for the memory cell if the memory cell is determined to have experienced Vccmin failure.

### BACKGROUND OF THE INVENTION

1. Field of the Invention

The invention relates generally to semiconductor integrated circuit design and manufacturing, and, more particularly, to memory products with repair schemes for Vccmin failure using redundancy memory cells, and manufacturing methods thereof.

2. Description of the Related Art

Data storage for processor-based systems employs semiconductor memory, popular types of which comprise Static Random Access Memory (SRAM), Dynamic Random Access Memory (DRAM) and Flash memory.

In memory design, respective memory types have respective storage mechanisms. For example, SRAM uses a cross-coupled inverter pair for storing information. This enables each inverter to maintain data for the other of the pair. The storage mechanisms are connected by bit lines and word lines. In SRAM access circuitry, to write “1” in the SRAM cell, bit line is driven as “1”, and bit line bar is driven as “0”. Next, transfer MOS is turned on by setting the word line to high, such that the values on the bit lines are written to the cell. To read data, bit lines are pulled up to open transfer MOS. One inverter can pull one bit line low while the other bit lines remain high. The difference between two bit lines is detected to read data. Redundancy repair schemes are particularly provided for particle defects in semiconductor memory. Redundancy memory cells can improve power consumption of memory, or enhance yield during manufacture.

Memory cells can be driven under a specific voltage. Vccmin is the minimum operating voltage under which memory cells can function properly in a full temperature range. In some conditions, such as circuitry mismatch between cell connections, the Vccmin for a specific memory cell may be higher. The specific memory cell cannot be properly accessed if the operating voltage falls below the Vccmin for the specific memory cell, generating Vccmin failure, a major point of consideration in semiconductor memory, for which no solution is currently provided

### BRIEF SUMMARY OF THE INVENTION

Memory products and manufacturing methods thereof are provided. In the invention, in addition to the reparation of particle defects, redundancy memory cells are used as repair schemes for Vccmin failure.

An embodiment of a memory product comprises at least one memory cell and at least one redundancy memory cell. The memory cell and the redundancy memory cell have different physical or electronic properties. The memory cell is replaced with the redundancy memory cell if the memory cell is determined to have experienced Vccmin failure.

In an embodiment of a memory manufacturing method, at least one memory cell is manufactured, and at least one redundancy memory cell is manufactured, where the memory cell and the redundancy memory cell have different physical or electronic properties. It is determined whether the memory cell experiences Vccmin failure. If so, the memory cell is replaced by the redundancy memory cell.

An embodiment of a memory product comprises at least one memory cell and at least one redundancy memory cell. The memory cell has a first cell size, and the redundancy memory cell has a second cell size, where the second cell size exceeds the first cell size. If the memory cell is determined to have experienced Vccmin failure, the memory cell is replaced with the redundancy memory cell.

In an embodiment of a memory manufacturing method, at least one memory cell having a first cell size is manufactured, and at least one redundancy memory cell having a second cell size is manufactured, where the second cell size exceeds the first cell size. It is determined whether the memory cell experiences Vccmin failure. If so, the memory cell is replaced by the redundancy memory cell.

An embodiment of a memory product comprises at least one memory cell and at least one redundancy memory cell. The memory cell has a first threshold voltage, and the redundancy memory cell has a second threshold voltage, where the second threshold voltage is less than the first threshold voltage. If the memory cell is determined to have experienced Vccmin failure, the memory cell is replaced with the redundancy memory cell.

In an embodiment of a memory manufacturing method, at least one memory cell having a first threshold voltage is manufactured, and at least one redundancy memory cell having a threshold voltage is manufactured, where the second threshold voltage is less than the first threshold voltage. It is determined whether the memory cell has experienced Vccmin failure. If so, the memory cell is replaced by the redundancy memory cell.

An embodiment of a memory product comprises at least one memory cell and at least one redundancy memory cell. The memory cell has a first oxide thickness, and the redundancy memory cell has a second oxide thickness, where the second oxide thickness is less than the first oxide thickness. If the memory cell is determined to have experienced Vccmin failure, the memory cell is replaced with the redundancy memory cell.

In an embodiment of a memory manufacturing method, at least one memory cell having a first oxide thickness is manufactured, and at least one redundant memory cell having a second oxide thickness is manufactured, where the second oxide thickness is less than the first oxide thickness. It is determined whether the memory cell has experienced Vccmin failure. If so, the memory cell is replaced by the redundancy memory cell.

Memory products and manufacturing methods thereof may take the form of program code embodied in a tangible media. When the program code is loaded into and executed by a machine, the machine becomes an apparatus for practicing the disclosed method.

### BRIEF DESCRIPTION OF THE DRAWINGS

The invention will become more fully understood by referring to the following detailed description with reference to the accompanying drawings, wherein:

FIG. 1 is a schematic diagram illustrating an embodiment of a memory product;

FIG. 2 is a flowchart of an embodiment of a memory manufacturing method; and

FIG. 3 is a flowchart of an embodiment of a memory manufacturing method.

### DETAILED DESCRIPTION OF THE INVENTION

Memory products and manufacturing methods thereof are provided.

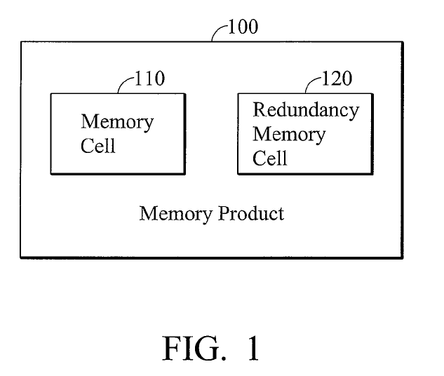

FIG. 1 is a schematic diagram illustrating an embodiment of a memory product.

As shown in FIG. 1, the memory product 100 comprises at least one memory cell 110 and at least one redundancy memory cell 120. The memory product 100 may be SRAM, DRAM, flash memory, and others. The memory cell 110 and the redundancy memory cell 120 have the same circuit structure. Any kind of memory structure can be applied to the memory cell 110 and the redundancy memory cell 120. For example, the memory cell 110 and the redundancy memory cell 120 may be 1 transistor cell (capacitor) for DRAM, floating gate cell for flash memory, or 6 transistor CMOS cell for SRAM. The structures of memory cells are well known, and omitted herefrom. It is noted that the connections between the memory cell 110 and the redundancy memory cell 120 are omitted from FIG. 1. It is understood that the memory cell 110 and the redundancy memory cell 120 may have different physical or electronic properties. For example, the memory cell size, oxide thickness, and the threshold voltage of the memory cell 110 and the redundancy memory cell 120 may be different. It is understood that Vccmin may be related to memory cell size, oxide thickness, and threshold voltage, and others. The difference in physical or electronic properties for the memory cell 110 and the redundancy memory cell 120 can be used as repair schemes for Vccmin failure. If the memory cell 110 has Vccmin failure, the redundancy memory cell 120 can be used to replace the memory cell 110.

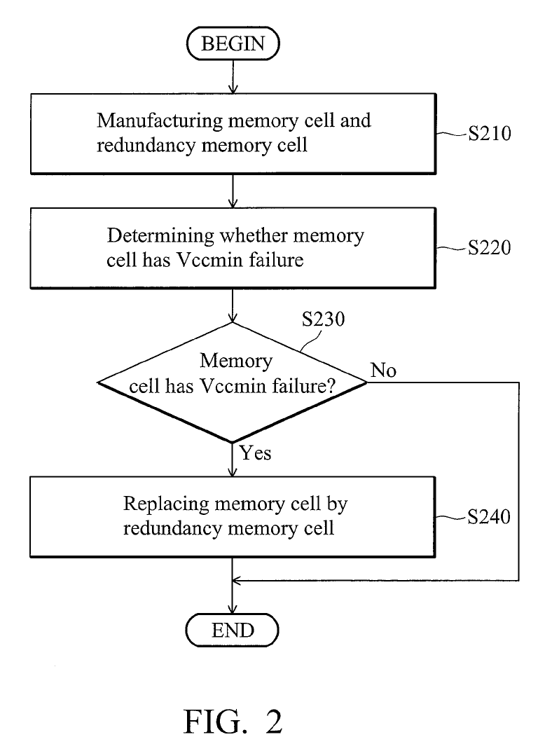

FIG. 2 is a flowchart of an embodiment of a memory manufacturing method.

In step S210, at least one memory cell 110 and at least one redundancy memory cell 120 are manufactured. It is understood that the memory cell 110 and the redundancy memory cell 120 have the same circuit structure, but have different physical or electronic properties. As described, the physical properties comprise the memory cell size, oxide thickness, and others. The electronic properties comprise the threshold voltage, and others. In step S220, it is determined whether the memory cell 110 has Vccmin failure. It is understood that the evaluation of the memory cell 110 with Vccmin failure is to determine whether an operating voltage for the memory cell 110 exceeds a predetermined threshold. If not (No in step S230), the procedure is complete to obtain a memory product. If so (Yes in step S230), in step S240, the memory cell 110 is replaced by the redundancy memory cell 120.

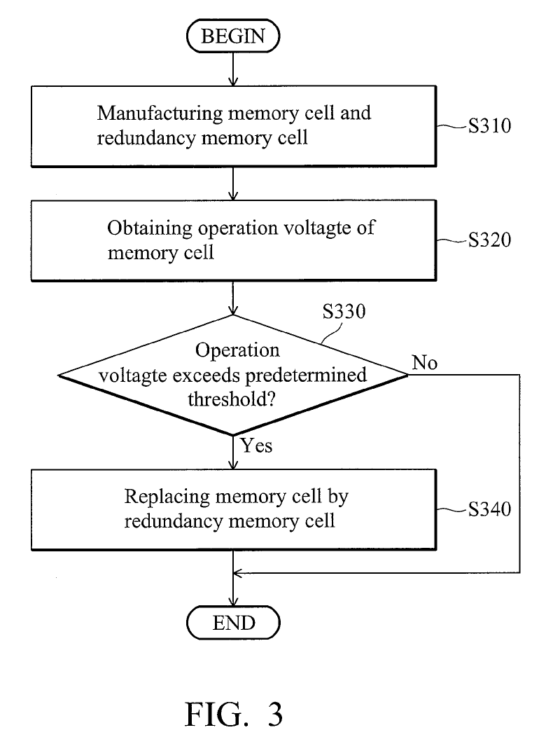

FIG. 3 is a flowchart of an embodiment of a memory manufacturing method.

In step S310, at least one memory cell and at least one redundancy memory cell are manufactured. It is understood that the memory cell and the redundancy memory cell have the same circuit structure, but have different physical or electronic properties. In some embodiments, the cell size of the redundancy memory cell 120 exceeds that of the memory cell 110. More specifically, the cell size of the redundancy memory cell 120 is at least 15% larger than that of the memory cell 110. Since Vccmin is related to memory cell size, and larger cell size corresponds to lower Vccmin, the redundancy memory cell 120 having larger cell size can be used as repair schemes for Vccmin failure if the memory cell 110 has Vccmin failure. In some embodiments, the oxide thickness of the redundancy memory cell 120 is smaller than that of the memory cell 110. Since Vccmin is related to oxide thickness, and less oxide thickness corresponds to lower Vccmin, the redundancy memory cell 120 having less oxide thickness can be used as repair schemes for Vccmin failure if the memory cell 110 has Vccmin failure. In some embodiments, the threshold voltage of the redundancy memory cell 120 is below that of the memory cell 110. More specifically, the threshold voltage of the redundancy memory cell 120 is at least 15% below that of the memory cell 110. Since Vccmin is related to threshold voltage, and smaller threshold voltage corresponds to lower Vccmin, the redundancy memory cell 120 having smaller threshold voltage can be used as repair schemes for Vccmin failure if the memory cell 110 has Vccmin failure. It is understood that, during manufacture of the memory product 100, the memory cell 110 is manufactured under a first doping concentration on channels, and the redundancy memory cell 120 is manufactured under a second doping concentration on channels, where the second doping concentration is thicker than the first doping concentration, such that the threshold voltage of the redundancy memory cell 120 is less than that of the memory cell 110. In step S320, the operating voltage for the memory cell 110 is obtained, and in step S330, it is determined whether the operating voltage exceeds a predetermined threshold. If not (No in step S330), the procedure is complete to obtain a memory product. If so (Yes in step S330), in step S340, the memory cell 110 is replaced by the redundancy memory cell 120.

Memory products and manufacturing methods thereof, or certain aspects or portions thereof, may take the form of program code (i.e., executable instructions) embodied in tangible media, such as products, floppy diskettes, CD-ROMS, hard drives, or any other machine-readable storage medium, wherein, when the program code is loaded into and executed by a machine, such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine, such as a computer, the machine becomes an apparatus for practicing the disclosed methods. When implemented on a general-purpose processor, the program code combines with the processor to provide a unique apparatus that operates analogously to application specific logic circuits.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A memory product, comprising:
at least one memory cell having a first cell size; and
at least one redundancy memory cell having a second cell size, wherein the second cell size exceeds the first cell size, and further
wherein the memory cell is replaced by the redundancy memory cell if the memory cell is determined to have experienced Vccmin failure.

2. The memory product of claim 1 wherein evaluation of the memory cell with Vccmin failure determines whether an operating voltage for the memory cell exceeds a predetermined threshold.

3. The memory product of claim 1 wherein the second cell size is at least 15% larger than the first cell size.

4. The memory product of claim 1 wherein the memory cell comprises a SRAM, DRAM, or flash memory cell.

5. A memory product, comprising:
at least one memory cell having a first threshold voltage; and
at least one redundancy memory cell having a second threshold voltage,
wherein the second threshold voltage is less than the first threshold voltage, and further
wherein the memory cell is replaced with the redundancy memory cell if the memory cell is determined to have experienced Vccmin failure.

6. The memory product of claim 5 wherein evaluation of the memory cell with Vccmin failure determines whether an operating voltage for the memory cell exceeds a predetermined threshold.

7. The memory product of claim 5 wherein the second threshold voltage is at least 15% less than the first threshold voltage.

8. The memory product of claim 5 wherein the memory cell comprises a SRAM, DRAM, or flash memory cell.

9. The memory product of claim 5 wherein the memory cell is manufactured under a first doping concentration, and the redundancy memory cell is manufactured under a second doping concentration, wherein the second doping concentration is thicker than the first doping concentration.

10. A memory product, comprising:
at least one memory cell having a first oxide thickness; and
at least one redundancy memory cell having a second oxide thickness,
wherein the second oxide thickness is less than the first oxide thickness, and further
wherein the memory cell is replaced with the redundancy memory cell if the memory cell is determined to have experienced Vccmin failure.

11. The memory product of claim 10 wherein evaluation of the memory cell with Vccmin failure determines whether an operating voltage for the memory cell exceeds a predetermined threshold.

12. The memory product of claim 10 wherein the memory cell comprises a SRAM, DRAM, or flash memory cell.

13. A memory manufacturing method, comprising:
manufacturing at least one memory cell having a first cell size;
manufacturing at least one redundancy memory cell having a second cell size,
wherein the second cell size exceeds the first cell size;
evaluating whether the memory cell has experienced Vccmin failure, and
if so, replacing the memory cell with the redundancy memory cell.

14. The method of claim 13 further comprising determining whether an operating voltage for the memory cell exceeds a predetermined threshold to determine whether the memory cell has experienced Vccmin failure.

15. The method of claim 13 further comprising manufacturing the redundancy memory cell having the second cell size at least 15% larger than the first cell size.

16. The method of claim 13 wherein the memory cell comprises a SRAM, DRAM, or flash memory cell.

17. A memory manufacturing method, comprising:
manufacturing at least one memory cell having a first threshold voltage;
manufacturing at least one redundancy memory cell having a second threshold voltage, wherein the second threshold voltage is less than the first threshold voltage;
evaluating whether the memory cell has experienced Vccmin failure, and
if so, replacing the memory cell with the redundancy memory cell.

18. The method of claim 17 further comprising determining whether an operating voltage for the memory cell exceeds a predetermined threshold to determine whether the memory cell has experienced Vccmin failure.

19. The method of claim 17 further comprising manufacturing the redundancy memory cell having the second threshold voltage at least 15% lower than the first threshold voltage.

20. The method of claim 17 wherein the memory cell comprises a SRAM, DRAM, or flash memory cell.

21. The method of claim 17 further comprising:
manufacturing the memory cell under a first doping concentration;
manufacturing the redundancy memory cell under a second doping concentration,
wherein the second doping concentration is thicker than the first doping concentration.

22. A memory manufacturing method, comprising:
manufacturing at least one memory cell having a first oxide thickness;
manufacturing at least one redundancy memory cell having a second oxide thickness, where the second oxide thickness is less than the first oxide thickness,
evaluating whether the memory cell has experienced Vccmin failure; and
if so, replacing the memory cell with the redundancy memory cell.

23. The method of claim 22 further comprising determining whether an operating voltage for the memory cell exceeds a predetermined threshold to determine whether the memory cell has experienced Vccmin failure.

24. The method of claim 22 wherein the memory cell comprises a SRAM, DRAM, or flash memory cell.

25. A memory product, comprising:
at least one memory cell; and
at least one redundancy memory cell,
wherein the memory cell and the redundancy memory cell have different physical or electronic properties, and the memory cell is replaced with the redundancy memory cell if the memory cell is determined to have experienced Vccmin failure.

26. The memory product of claim 25 wherein the physical properties comprise memory cell size and oxide thickness.

27. The memory product of claim 25 wherein the electronic properties comprise threshold voltage.

28. The memory product of claim 25 wherein evaluation of the memory cell with Vccmin failure determines whether an operating voltage for the memory cell exceeds a predetermined threshold.

29. A memory manufacturing method, comprising:
manufacturing at least one memory cell;
manufacturing at least one redundancy memory cell, wherein the memory cell and the redundancy memory cell have different physical or electronic properties,
evaluating whether the memory cell has experienced Vccmin failure; and
if so, replacing the memory cell with the redundancy memory cell.

30. The method of claim 29 further comprising determining whether an operating voltage for the memory cell exceeds a predetermined threshold to determine whether the memory cell has experienced Vccmin failure.

31. The method of claim 29 wherein the physical properties comprise memory cell size and oxide thickness.

32. The method of claim 29 wherein the electronic properties comprise threshold voltage.
